(19) United States
(12) Patent Application Publication
(10) Pub. No.: US 2026/0235672 A1
(43) Pub. Date: Aug. 13, 2026

(54) Digital Glitch Sensor

(71) Applicant: Google LLC, Mountain View, CA (US)

(72) Inventors: Prathamesh Ramesh Save, San Jose, CA (US); Vinoth Kumar Deivasigamani, San Diego, CA (US)

(73) Assignee: Google LLC, Mountain View, CA (US)

(21) Appl. No.: 19/155,757

(22) PCT Filed: May 24, 2023
(86) PCT No.: PCT/US2023/023373

§ 371 Date: Aug. 12, 2025

(51) Int. Cl. G01R 31/3183; G01R 19/165; G01R 23/00; G01R 31/317; G08B 21/18

(52) U.S. Cl. CPC G01R 31/318328; G01R 19/16528; G01R 23/005; G01R 31/31703; G01R 31/31726; G08B 21/185

(57) ABSTRACT

Methods, systems, and apparatus, including computer programs encoded on a computer storage medium, for performing a dynamic frontend victimization process. In one aspect, a system comprises a digital glitch detector comprising a pair of shift feedback registers that are driven by a clock signal, and control logic that is configured to detect a glitch when an output of the pair of shift feedback registers becomes unsynchronized.

### BACKGROUND

This specification relates to techniques for detecting glitches using a digital glitch sensor.

Hardware devices that execute on clock signals can malfunction or suffer degraded performance in the presence of circuit glitches, which broadly refer to deviations in clock frequency or voltage of a digital circuit. For example, a clock frequency glitch can occur when the clock frequency increases beyond an operational threshold, and a voltage glitch can occur when the voltage increases above a maximum voltage threshold or drops below a minimum voltage threshold. When these events occur, they can cause the circuit to behave differently than it was designed to behave. For example, data that is supposed to be propagated between storage elements, e.g., flip flops, may not be propagated properly.

Glitches can negatively impact the performance and stability of hardware devices because the glitches can cause the digital circuits to generate unexpected output signals. In addition, glitches increase the security risk of the device performing unexpected or unauthorized behavior, e.g., by executing unauthorized code.

It is important to detect such events so that the device can be restored to a proper state rather than continuing to operate in an unexpected manner. However, glitches are often very difficult to detect because the event causing the glitch, e.g., a voltage drop, can last for a very short time, e.g., less than one clock cycle.

Conventional techniques for detecting glitches are complex, expensive, and power inefficient. These undesirable properties make many conventional glitch detectors unsuitable for battery-powered devices such as mobile phones in which power efficiency is critical and silicon area is limited. In addition, the complexity and power usage of conventional glitch detection circuits are often makes them unsuitable for low-power techniques, such as dynamic voltage and frequency scaling (DVFS).

### SUMMARY

This specification describes techniques and systems for implementing a digital glitch sensor for detecting various types of glitches in a digital circuit. In this specification, a glitch refers to a deviation from expected operational parameters of a clock signal or a voltage level for a digital circuit or a digital device. Thus, the types of glitches that can be detected by the glitch detector described in this specification can include a clock frequency glitch, an under-voltaging glitch, or an over-voltaging glitch, to name just a few examples. The digital glitch sensor as disclosed herein efficiently detects such frequency and voltage glitches.

Particular embodiments of the subject matter described in this specification can be implemented so as to realize one or more of the following advantages.

The digital glitch sensor described in this specification provides improved power efficiency in detecting glitches in a digital circuit while being a simpler implementation in comparison to some prior techniques. The digital glitch sensor described in this specification detects circuit glitches by implementing a relatively simple and power-efficient circuit structure. The circuit structure of the digital glitch sensor implements one or more linear feedback shift register (LFSR) pairs to perform glitch detection by determining whether a pair of the LFSRs have become unsynchronized due to a circuit violation, e.g., a setup violation or a hold violation. The digital glitch sensor can efficiently detect glitches using relatively low amounts of power. By efficiently detecting glitches in the digital circuit, the digital glitch sensor can improve the overall security and power efficiency of the device. Additionally, the digital glitch sensor allows for adjusting the clock frequency or a voltage of the digital circuit in order to perform dynamic voltage and frequency scaling (DVFS) techniques without requiring extra characterization work in analyzing the circuit.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a block diagram of an example system.

FIG. 2 is a block diagram of an example digital glitch sensor.

FIG. 3. is a block diagram of an example linear feedback shift register (LFSR).

FIG. 4 is a flow diagram of an example process for detecting a glitch in a digital circuit.

Like reference numbers and designations in the various drawings indicate like elements.

### DETAILED DESCRIPTION

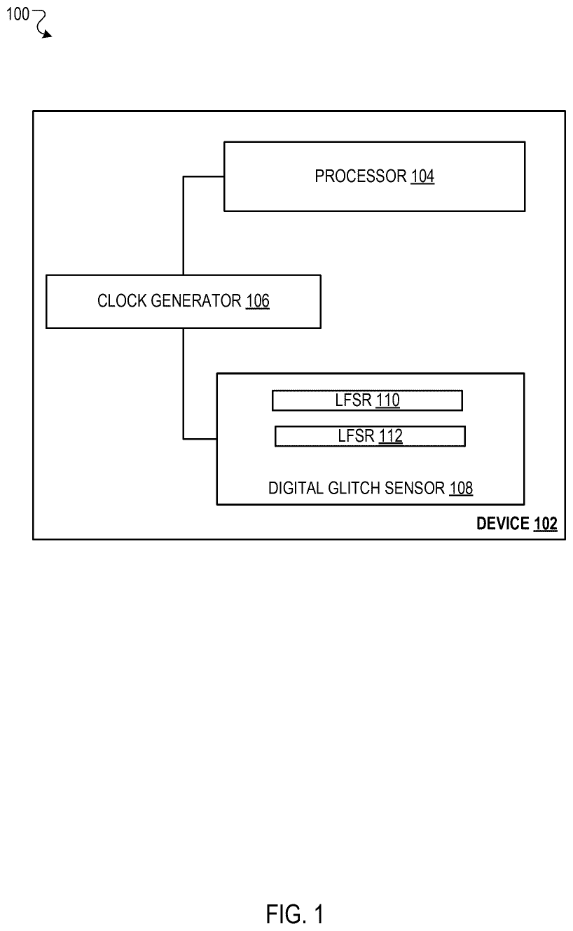

FIG. 1 shows an example system 100. The system 100 is an example of a system in which the systems, components, and techniques described below are implemented.

System 100 includes a device 102. The device 102 is an example of a device that can be installed on or integrated into any appropriate computing device, which may be referred to as a host device. For example, a host device can be a cell phone, a laptop, a tablet, or a monitor. Because the techniques described in this specification are particularly suited to saving power consumption for the host device, the device 102 can be particularly suited to saving power consumption for the host device.

The device 102 includes a processor 104, a clock generator 106, and a digital glitch sensor 108. The device 102 uses the processor 104 to receive and send data by processing software instructions. The processor 104 can include one or more digital circuits. The clock generator 106 is an oscillator circuit that generates a clock signal for synchronizing the operation of a digital circuit of the processor 104. The digital glitch sensor 108 is configured to detect glitches of the clock signal generated by the clock generator 106 for the overall function of the device 102.

Glitches can include a clock frequency glitch, an under-voltaging glitch, and an over-voltaging glitch. A clock frequency glitch is generally caused by an increase in the clock frequency over an operational clock frequency threshold and usually lasts for a relatively small amount of time and typically without an adjustment of the voltage. The clock frequency often resumes normal operation after a clock frequency glitch, thus making them difficult to detect.

An under-voltaging glitch is generally caused by a decrease in voltage under a minimum operational voltage, which usually lasts for a relatively small amount of time and typically without an adjustment of the clock frequency.

An over-voltaging glitch is generally caused by an increase in voltage over a maximum operational voltage, which usually lasts for a relatively small amount of time and typically without an adjustment of the clock frequency.

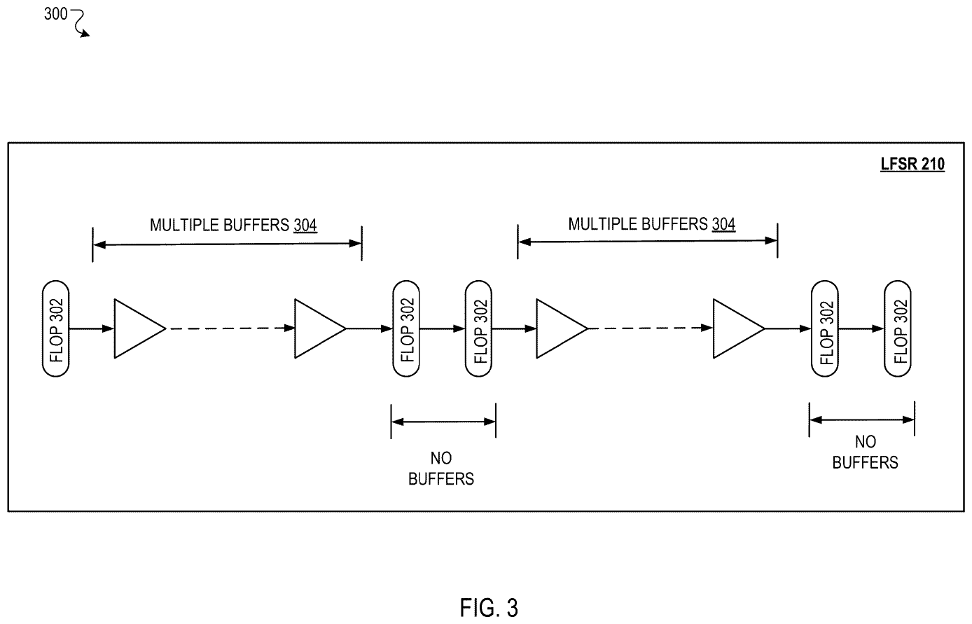

Clock frequency glitches and under-voltaging glitches can result in set-up violations of the digital circuit, and over-voltaging glitches can result in hold violations of the digital circuit, as described in further detail below with reference to FIG. 3.

A set-up violation is a violation that can occur from a clock frequency glitch or an under-voltaging glitch when data is not captured adequately within an LFSR because the LFSR does not register the value in a stable manner for a sufficient amount of time due to the relatively high clock frequency or the relatively low voltage.

A hold violation is a violation that can occur from an over-voltaging glitch when the digital circuit operates at a higher voltage than a threshold, and the data changes too rapidly for the LFSR to hold the value in a stable manner for a sufficient amount of time.

The digital glitch sensor 108 implements one or more pairs of linear feedback shift registers (LFSRs) 110 and 112 to perform glitch detection by monitoring for set-up violations and hold violations of a digital circuit. An LSFR is a register circuit that outputs a pseudo-random sequence of values by processing an input signal.

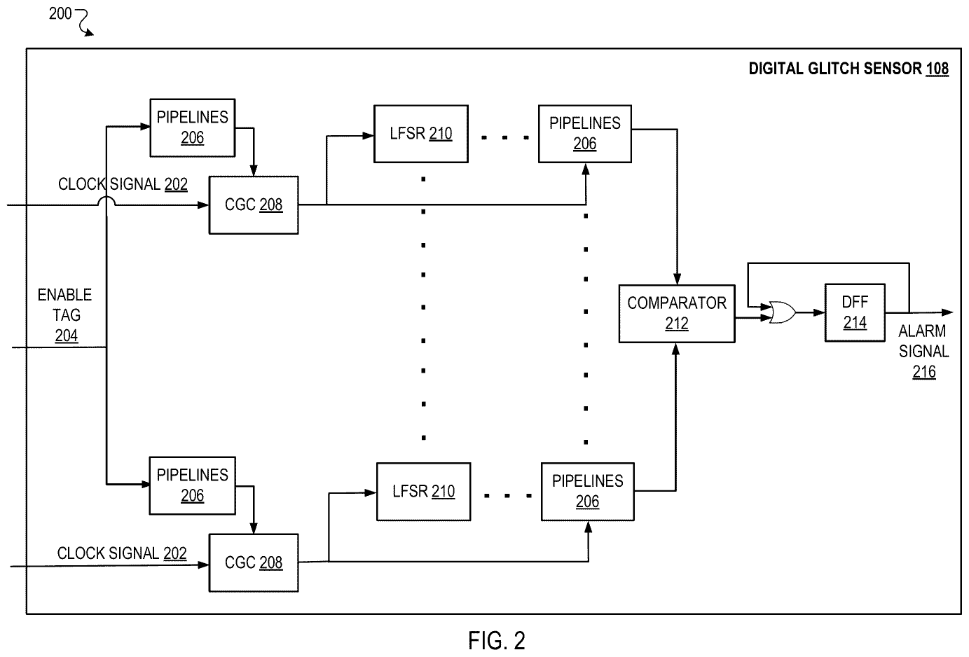

The digital glitch sensor 108 passes an input clock signal through a pair of LSFRs, and the digital glitch sensor compares the outputs of a pair of LFSRs to determine whether the pair of LFSRs is synchronized or unsynchronized, and the digital glitch sensor 108 can generate an alarm signal based on whether the LFSRs are synchronized or unsynchronized, as described in further detail below with reference to FIGS. 2-4.

FIG. 2 is a block diagram of an example digital glitch sensor. For convenience, the digital glitch sensor will be described as being implemented by a system. For example, a system, e.g., the system 100 of FIG. 1, appropriately configured in accordance with this specification, can implement the digital glitch sensor 108.

The digital glitch sensor 108 is configured to detect a clock frequency glitch, an under-voltaging glitch, and an over-voltaging glitch of a digital circuit of the system.

The digital glitch sensor 108 includes pipelines 206, a clock generation controller (CGC) 208, LFSRs 210, a comparator 212, and a delay flip flop (DFF) 214.

The system enables and disables the digital glitch sensor 108 using an enable tag 204. Once enabled, the system runs a clock signal 202 through the digital glitch sensor 110. The digital glitch sensor 108 uses multiple LFSRs 210 to process data of the clock signal 202, and the digital glitch sensor 108 uses the comparator 212 and the DFF 214 to determine whether the multiple LFSRs 210 are unsynchronized based on the outputs of the multiple LFSRs 210. The DFF 214 is a circuit that delays the change of state of the output signal of the digital glitch sensor 108 until a next rising edge of the clock signal 202.

In particular, the digital glitch sensor 108 includes multiple LFSRs 210 placed physically apart from each other in parallel in the same voltage domain and the same clock domain as the digital circuit. The pipelines 206 physically separate the multiple LFSRs 210 from each other and ensure that the outputs of the LFSRs 210 will arrive simultaneously at the comparator 212. The CGC 208 can generate a clock generation control signal to stop the clock signal 202 from running through the LFRSs 210.

In normal operation, the LFSRs 210 operate synchronously (e.g., in sync). The LFSRs 210 are all supplied with the same clock signal 202, and the LFSRs 210 implement a polynomial function to process the clock signal 202. LFSRs 210 in sync generate the same output by implementing the polynomial function and processing the same clock signal 202. In particular, the polynomial function can be a primitive polynomial function, e.g., a primordial function. An LFSR 210 can process the clock signal 202, which includes an input data sequence of values. The LFSR 210 implements the polynomial function to generate an output signal over a relatively large amount of time, where the output signal includes a sequence of pseudo-random non-repetitive values.

In particular, the LFSR 210 processes the input data sequence of values by applying the polynomial function to each value, x. The value can be a value of a register bit (e.g., 0 or 1). For example, a 32-bit LFSR 210 can be configured to implement a particular polynomial function (e.g., x³²+x²²+x²+x¹+1) for the input data sequence. The primitive polynomial function is such that the same output is not repeated until all possible values of the output are generated by the LFRS 210. This feature ensures that once two LSFR's go out of sync, the probability that they will re-synchronize is so vanishingly low so as to be effectively zero. In this example, the 32-bit LFSR 210 generates the output signal for each value. In normal operation, the multiple LFSRs 210 generate the same output value for each input value of the clock signal 202.

However, in some examples, one or more of the LFSRs 210 can experience a glitch, such as a clock frequency glitch or a voltage glitch. The glitch can result in a set-up violation or a hold violation that negatively affects the digital circuit, as described in further detail below with reference to FIG. 3.

The digital glitch sensor 110 can detect a glitch by determining that the multiple LFSRs 210 are unsynchronized based on a comparison of the outputs of the LFSRs 210. If the multiple LFSRs are unsynchronized and are not in normal operation, the multiple LFSRs 210 do not output the same value (e.g., the LFSRs 210 are implementing the polynomial function for the same input and generating a different output). Any occurrence of a clock frequency glitch or a voltage glitch can put one or more of the LFSRs 210 out of sync with other LFSRs 210. Thus, the probability of the LFSRs 210 going out of sync in presence of a glitch becomes very high and the probability of the LFSRs 210 resynchronization becomes very low, which results in effective detectability.

Additionally, the digital glitch sensor 108 can efficiently detect a glitch because the multiple LFSRs 210 are physically placed apart from each other, such that the probability of the LFSRs 210 observing an identical glitch at the same instance of time is infinitesimally low.

The digital glitch sensor 108 can compare the output of a pair of LFSRs 210 using the comparator 212, and the digital glitch sensor 110 activates an alarm signal 216 indicating to the system that a glitch has taken place. Thus, the digital glitch sensor can detect a glitch without extensive characterization of the digital circuit.

To make the digital glitch sensor 108 highly sensitive to clock frequency glitches and voltage glitches, the digital glitch sensor 108 implements different patterns of consecutive storage elements for each LFSR 210, such as flip flop registers (e.g., flip flops) and delay elements (e.g., buffers), as described in further detail below with reference to FIG. 3. The different patterns of delays between the different LFSRs will cause the LFSRs to go out of sync even if the identical glitch pattern was observed at the exact same time by all of the LFSRs.

In some examples, to support DVFS techniques, the device can implement variations of the digital glitch sensor 108. Each variation of the digital glitch sensor 108 includes a different number of LFSRs 210 optimized for a given voltage level and clock frequency of operation. The device can implement DVFS techniques by shifting the voltage level and the clock frequency of the digital circuit.

The device can perform software execution to select a set of digital glitch sensors 110 to be used for a given voltage level and clock frequency of operation, and the device can disable other variations of the digital glitch sensor 108, which increases the efficiency of the overall system by allowing for low power implementations of DVFS techniques.

FIG. 3 is a block diagram of an example LFSR. For convenience, the LFSR will be described as being implemented by a digital glitch sensor in a system. For example, a digital glitch sensor in a system, e.g., the digital glitch circuit in the system 100 of FIG. 1, appropriately configured in accordance with this specification, can implement the LFSR 210.

The LFSR 210 is configured to implement different patterns of storage elements and delay elements for glitch detection. The LFSR 210 includes a chain of flip flops (e.g., flops) 302 and multiple buffers 304.

A flip flop is a circuit with two stable states that can store data, such a single bit of data (e.g., 0 or 1). A buffer is a delay element implemented as a circuit that isolates an input signal from an output signal. The buffers isolates the input signal by delaying processing the output signal.

Clock frequency glitches and voltages glitches result in circuit violations, such as set-up violations and hold violations. The digital glitch sensor can use LFSRs 210 to detect set-up violations and hold violations by implementing different patterns of flops 302 and multiple buffers 304 in each LFSR 210.

In normal operation, the LFSRs 210 operate with no set-up violations or hold violations, and the outputs of LFSRs 210 are synchronized. The LFSRs 210 are synchronized in the absence of glitches because they are configured to process signals including input sequences of data using the different patterns of flops 302 and multiple buffers 304 to generate a same output sequence of data. However, if a set-up violation or a hold violation takes place, the values of the output sequence of data of a pair of LFSRs 210 in the digital glitch sensor become unsynchronized because a flop 302 in the LFSR 210 fails to adequately process the input sequence of data, which allows the digital glitch sensor to detect the glitch.

The different patterns of the LFSRs 210 allow the digital glitch sensor to detect violations of the circuit caused by the various glitches. Each LFSR 210 includes a different chain of flops 302, multiple buffers 304, and segments without buffers (e.g., no buffers). A chain of two flops 302 with multiple buffers 304 between the two flops 302 can result in a set-up violation, and a chain of two flops 302 with no buffers between the two flops 302 can result in a hold violation, which causes the digital glitch sensor to detect a corresponding glitch.

Each LFSR 210 has a different pattern of buffers placed between two flops in the chain of the LFSR 210. In this example, the chain has a pattern of a flop 302, multiple buffers 304, a flop 302, no buffers, a flop 302, multiple buffers 304, and a flop 302. In some other examples, the chain can have a pattern of a flop 302, multiple buffers 304, a flop 302, multiple buffers 304, a flop 302, no buffers, and a flop 302. Thus, even if multiple LFSRs 210 experienced a set-up violation caused by clock frequency glitch or an under-voltaging glitch, or a hold violation caused by an over-voltaging glitch simultaneously, the different patterns of the chains in the LFSR 210 will continue to cause the LSFRs to go out of sync and for the digital glitch sensor to detect the glitch.

In particular, a set-up violation occurs from a clock frequency glitch when data from a first flop 302 is not captured by a second flop 302 because the first flop 302 did not hold the value in a stable manner for a sufficient amount of time. For example, the first flop 302 may not hold the value adequately if the digital circuit is operating at a frequency higher than a threshold (e.g., a flop 302 is designed to function at a threshold of 100 MHz, but the clock frequency is set at 150 MHz). In this example, the set-up violation causes the LFSRs 210 to go out of sync because values of the output signal are not adequately propagated by the flops 302 due to the clock frequency glitch. In particular, the clock frequency glitch causes an interruption of the implementation of the polynomial because the flops 302 do not properly propagate the input sequence of values. The interruption in implementing the polynomial causes the LFSRs 210 to generate different output values because the input sequence of values is propagated differently for each LFSR 210, e.g., the LFSRs 210 use different patterns of flops 302 and multiple buffers 304 for propagating the input sequence of values.

In another case, a set-up violation can result from an under-voltaging glitch because under-voltaging decreases the speed of the current through the digital circuit, which causes the digital circuit to operate at a lower clock frequency. In this case, the digital circuit loses functionality, and data is consequentially not captured across flops 302. In particular, the under-voltaging glitch causes an interruption of the implementation of the polynomial because of the decrease of the speed of the current through the digital circuit.

The under-voltaging glitch causes the LFSRs 210 to generate different output values because the input sequence of values is propagated differently for each LFSR 210, e.g., the LFSRs 210 use different patterns of flops 302 and multiple buffers 304 for propagating the input sequence of values.

The digital glitch sensor can implement LFSRs 210 with multiple buffers 304 between two flops 302 to detect the set-up violation caused by clock frequency glitches and under-voltaging glitches. The multiple buffers 304 build a delay between two flops 302, which increases the probability that a set-up violation will take place if there is a clock frequency glitch or an under-voltaging glitch. In particular, if the clock frequency goes beyond the threshold, the data from a first flop 302 will not reach the next flop 302 within a certain set-up time due to the delay of the multiple buffers 304. The set-up time is the amount of time during which data signals are stable before the next clock edge occurs.

Additionally, if the voltage drops below a certain voltage, the current through the digital circuit will slow down, and data from a first flop 302 will not reach the next flop 302 within the set-up time.

The system can determine a number of multiple buffers 304 between the two flops 302 based on the set-up time of the flop 302. The number of buffers parameter can be set into the design of the glitch sensor during software instruction. The number of buffers to be implemented in an LFSR 210 to detect a set-up violation is defined by Equation 1:

$$Number of Buffers = \frac{\begin{matrix}Time Period of Clock - \\ Clock Uncertainty - Setup Time of Flop\end{matrix}}{Delay of Buffer} \qquad ( 1 )$$

where the time period of the clock is the time between each clock edge, and the clock uncertainty is the deviation of the actual arrival time of the clock edge with respect to the ideal arrival time of the clock edge. The delay of the buffer is a certain amount of time associated with the buffer.

Additionally, the digital glitch sensor can detect hold violations caused by an over-voltaging glitch using the chain of flops 302 of the LFSR 210. A chain with two subsequent flops 302 with no buffers in between increases the speed of the digital circuit, which increases the probability that a hold violation will take place. In particular, a hold violation occurs from an over-voltaging glitch when the digital circuit operates at a higher voltage than a threshold, and the output value of a first flop 302 changes too rapidly for the next flop 302 in the chain to capture it accurately. A chain with no buffers between two subsequent flops 302 can result in the output value of the first flop 302 changing rapidly because of the relatively high voltage, resulting in a hold violation.

In particular, the clock frequency glitch causes an interruption of the implementation of the polynomial because the flops 302 do not properly propagate the input sequence of values, which causes the LFSRs 210 to generate different output values because the input sequence of values is propagated differently for each LFSR 210.

Thus, the digital glitch sensor can effectively detect the glitch because the different patterns of the LFSRs 210 cause the pair of LFSRs 210 to generate different outputs when the LFSRs go out of sync. The LFSRs 210 are not likely to come back into sync because each LFSR propagates each value of the input sequence, which does not repeat values. The digital glitch sensor compares each output value of the LFSR 210, and the digital glitch system actives an alarm that indicates to the system that a glitch has taken place.

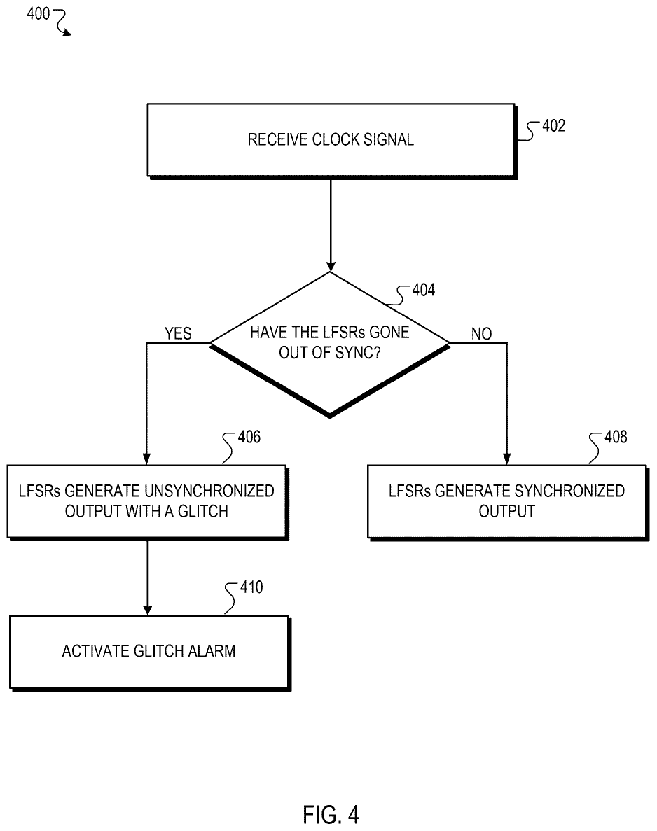

FIG. 4 is a flow diagram of an example process for detecting a glitch in a digital circuit. For convenience, the process 400 will be described as being performed by a digital glitch sensor. For example, the digital glitch sensor, e.g., the digital glitch sensor 110 of FIG. 1, appropriately configured in accordance with this specification, can perform the process 400.

The digital glitch sensor receives a clock signal (402). The system can generate a clock signal, and the digital glitch sensor can propagate the clock signal in order to perform glitch detection.

The digital glitch sensor determines whether the LFSRs have become unsynchronized (e.g., gone out of sync) (404). The digital glitch sensor uses multiple LFSRs to propagate the clock signal, and the digital glitch sensor compares output values from a pair of LFSRs to detect a glitch of the digital circuit. If the output values are different, the digital glitch sensor determines that the LFSRs have gone out of sync, and if the output values are the same, the digital glitch sensor determines that the LFSRs are synchronous and functioning in normal operation.

In some cases, if the digital glitch sensor determines that the LFSRs have gone out of sync, the digital glitch sensor determines that one or more of the LFSRs have generated an unsynchronized output associated with a glitch (406). The glitch can be a clock frequency glitch, an under-voltaging glitch, or a voltage glitch associated with a set-up violation or a hold violation.

In this case, the digital glitch sensor actives a glitch alarm that indicates a glitch of the clock signal (410). The glitch alarm indicates to the system that a glitch has taken place, and the system can disable the digital circuit to prevent decrease security of the system.

In some other cases, if the digital glitch sensor determines that the LFSRs have not gone out of sync, the digital glitch sensor determines that the LFSRs have generated a synchronized output (408). The digital glitch sensor refrains from activating the glitch alarm.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

In addition to the embodiments described above, the following embodiments are also innovative:

Embodiment 1 is a digital glitch detector comprising:
one or more pairs of feedback shift registers that are driven by a clock signal; and
control logic that is configured to detect a glitch when an output of the pair of feedback shift registers becomes unsynchronized.

Embodiment 2 is the digital glitch detector of embodiment 1, wherein each pair of feedback shift registers is configured to generate a synchronized output when the clock signal is operating normally.

Embodiment 3 is the digital glitch detector of any one of embodiments 1-2, wherein each feedback shift register has a different pattern of storage elements and delay elements.

Embodiment 4 is the digital glitch detector of embodiment 3, wherein each feedback shift register has a different pattern of storage elements and delay elements.

Embodiment 5 is the digital glitch detector of embodiment 3, wherein the pattern comprises consecutive sequences of storage elements and delay elements.

Embodiment 6 is the digital glitch detector of embodiment 5, wherein each pattern comprises a first storage element, multiple delay elements, a second storage element, and a third storage element without a delay element between the second storage element and the third storage element.

Embodiment 7 is the digital glitch detector of any one of embodiments 2-6, wherein the delay elements are buffers.

Embodiment 8 is the digital glitch detector of any one of embodiments 1-7, wherein the glitch detected by the digital glitch detector is a clock frequency spike.

Embodiment 9 is the digital glitch detector of any one of embodiments 1-7, wherein the glitch detected by the digital glitch detector is an over-voltage condition.

Embodiment 10 is the digital glitch detector of any one of embodiments 1-7, wherein the glitch detected by the digital glitch detector is an under-voltage condition.

Embodiment 11 is the method of anyone of any one of embodiments 1-7, wherein the digital glitch detector is configured to detect clock frequency spikes, over-voltage conditions, and under-voltage conditions.

Embodiment 12 is a method for detecting a glitch in a circuit, the method comprising:
receiving a clock signal;
processing the clock signal using one or more pairs of feedback shift registers.
detecting a glitch of the clock signal based on whether an output of the pair of feedback shift registers becomes unsynchronized; and
generating an alarm signal that indicates the glitch of the clock signal.

Embodiment 13 is the method of embodiment 12, wherein each pair of feedback shift registers is configured to generate a synchronized output when the clock signal is operating normally.

Embodiment 14 is the method of any one of embodiments 12-13, wherein each feedback shift register is implemented using a respective patter of storage elements and delay elements.

Embodiment 15 is the method of embodiment 14, wherein each feedback shift register has a different pattern of storage elements and delay elements.

Embodiment 16 is the method of embodiment 14, wherein the pattern comprises consecutive sequences of delay elements between pairs of storage elements.

Embodiment 17 is a system for detecting a digital glitch in a circuit, the system comprising:
a digital glitch sensor, wherein the digital glitch is configured to repeatedly perform operations comprising:
   receiving a clock signal;
   processing the clock signal using one or more pairs of feedback shift registers.
   detecting a glitch of the clock signal based on whether an output of the pair of feedback shift registers becomes unsynchronized; and
   generating an alarm signal that indicates the glitch of the clock signal.

Embodiment 18 is the system of embodiment 17, wherein each pair of feedback shift registers is configured to generate a synchronized output when the clock signal is operating normally.

Embodiment 19 is the system of any one of embodiments 17-18, wherein each feedback shift register is implemented using a respective patter of storage elements and delay elements.

Embodiment 20 is the system of embodiment 19, wherein each feedback shift register has a different pattern of storage elements and delay elements.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A digital glitch detector comprising:
one or more pairs of feedback shift registers that are driven by a clock signal; and
control logic that is configured to detect a glitch when an output of the pair of feedback shift registers becomes unsynchronized.

2. The digital glitch detector of claim 1, wherein each pair of feedback shift registers is configured to generate a synchronized output when the clock signal is operating normally.

3. The digital glitch detector of claim 1, wherein each feedback shift register has a different pattern of storage elements and delay elements.

4. The digital glitch detector of claim 3, wherein each feedback shift register has a different pattern of storage elements and delay elements.

5. The digital glitch detector of claim 3, wherein each of the different patterns comprises consecutive sequences of storage elements and delay elements.

6. The digital glitch detector of claim 5, wherein each of the different patterns comprises a first storage element, multiple delay elements, a second storage element, and a third storage element without a delay element between the second storage element and the third storage element.

7. The digital glitch detector of claim 3, wherein the delay elements are buffers.

8. The digital glitch detector of claim 1, wherein the glitch detected by the digital glitch detector is one or more of a clock frequency spike, an over-voltage condition, or an under-voltage condition.

9. (canceled)

10. (canceled)

11. The digital glitch detector of claim 1, wherein the digital glitch detector is configured to detect one or more of clock frequency spikes, over-voltage conditions, and under-voltage conditions.

12. A method for detecting a glitch in a circuit, the method comprising:
receiving a clock signal;
processing the clock signal using one or more pairs of feedback shift registers;
detecting a glitch of the clock signal based on whether an output of the pair of feedback shift registers becomes unsynchronized; and
generating an alarm signal that indicates the glitch of the clock signal.

13. The method of claim 12, wherein each pair of feedback shift registers is configured to generate a synchronized output when the clock signal is operating normally.

14. The method of claim 12, wherein each feedback shift register is implemented using a respective pattern of storage elements and delay elements.

15. The method of claim 14, wherein each feedback shift register has a different pattern of storage elements and delay elements.

16. The method of claim 14, wherein each of the different patterns comprises consecutive sequences of delay elements between pairs of storage elements.

17. A system for detecting a digital glitch in a circuit, the system comprising
a digital glitch sensor, wherein the digital glitch sensor is configured to repeatedly perform operations comprising:
receiving a clock signal;
processing the clock signal using one or more pairs of feedback shift registers;
detecting a glitch of the clock signal based on whether an output of the pair of feedback shift registers becomes unsynchronized; and
generating an alarm signal that indicates the glitch of the clock signal.

18. The system of claim 17, wherein each pair of feedback shift registers is configured to generate a synchronized output when the clock signal is operating normally.

19. The system of claim 17, wherein each feedback shift register is implemented using a respective pattern of storage elements and delay elements.

20. The system of claim 19, wherein each feedback shift register has a different pattern of storage elements and delay elements.

21. The method of claim 16, wherein each of the different patterns comprises a first storage element, multiple delay elements, a second storage element, and a third storage element without a delay element between the second storage element and the third storage element.

22. The system of claim 20, wherein each of the different patterns comprises a first storage element, multiple delay elements, a second storage element, and a third storage element without a delay element between the second storage element and the third storage element.
